(19) United States
(12) Patent Application Publication
(10) Pub. No.: US 2024/0004426 A1
(43) Pub. Date: Jan. 4, 2024

(54) IMAGE DISPLAY DEVICE

(71) Applicant: FUJIFILM Corporation, Tokyo (JP)

(72) Inventors: Naoyoshi YAMADA, Kanagawa (JP); Naoya SHIBATA, Kanagawa (JP)

(73) Assignee: FUJIFILM Corporation, Tokyo (JP)

(21) Appl. No.: 18/463,025

(22) Filed: Sep. 7, 2023

Related U.S. Application Data
(63) Continuation of application No. PCT/JP2022/008542, filed on Mar. 1, 2022.

(30) Foreign Application Priority Data
Mar. 22, 2021 (JP) 2021-047068

(51) Int. Cl. G06F 1/16; H01L 27/15; H10K 50/11; G02B 5/30

(52) U.S. Cl. CPC G06F 1/1616; G06F 1/1641; G02B 5/3025; H01L 27/156; H10K 50/11; G06F 1/1654

(57) ABSTRACT

Provided is an image display device that includes a plurality of image display units disposed adjacent to each other and is capable of reducing an interval between image display surfaces of the adjacent image display units. The image display device includes a plurality of image display units and polarizers disposed on image display surface sides of the image display units, in which the image display units are disposed adjacent to each other, and the polarizers contain a dichroic substance and a liquid crystal compound.

### CROSS-REFERENCE TO RELATED APPLICATIONS

This application is a Continuation of PCT International Application No. PCT/JP2022/008542 filed on Mar. 1, 2022, which claims priority under 35 U.S.C. § 119(a) to Japanese Patent Application No. 2021-047068 filed on Mar. 22, 2021. The above applications are hereby expressly incorporated by reference, in their entirety, into the present application.

### BACKGROUND OF THE INVENTION

### 1. Field of the Invention

The present invention relates to an image display device including a plurality of image display units.

### 2. Description of the Related Art

As a foldable image display device with a large screen, an image display device in which a plurality of image display units are arranged is known.

For example, JP2018-031884A describes, as a foldable image display device having two screens, an image display device (information processing device) including a first housing, a second housing, a first display unit provided on one surface of the first housing, a second display unit provided on one surface of the second housing, a connection unit connecting the first housing and the second housing such that the first housing and the second housing are rotatable and adjacent to each other, a detection unit detecting the postures of the first housing and the second housing, and a control unit controlling display on the first display unit and the second display unit based on the detection results of the detection unit, in which the control unit selects any one of the first housing or the second housing according to the postures of the first housing and the second housing in a case where the angle between the first housing and the second housing is in a predetermined range and controls display on the display unit of the selected housing.

As described in JP2018-031884A, in such an image display device having a plurality of image display units, for example, a liquid crystal display element, an organic electroluminescence (EL) display element, or the like is used as the image display unit.

Here, as described in JP2020-056929A, a polarizer (polarizing plate) is used for these image display elements.

For example, in a case of a liquid crystal display element, polarizers in which directions of absorption axes are orthogonal to each other are provided to sandwich a liquid crystal layer in which liquid crystal cells are arranged. Further, an organic EL display element, a light emitting diode (LED) display element, a micro LED display element, or the like typically includes an antireflection film obtained by combining a linear polarizer and a V4 wavelength plate, on an image display surface side.

### SUMMARY OF THE INVENTION

As described in JP2020-056929A, polyvinyl alcohol (PVA) containing iodine is suitably used as a polarizer in such an image display element due to a high polarization degree.

As in the image display device described in JP2018-031884A, in many cases, one image is displayed on a plurality of screens of an image display device in which a plurality of image display units are arranged.

In such a case, it is preferable that the gap between the image display surfaces, that is, the joint between the image display surfaces is small in the display image.

However, according to the examination conducted by the present invention, in an image display device of the related art in which a plurality of image display elements having a polarizer are arranged as image display units, image display surfaces are spaced from each other in the adjacent image display units due to the polarizer.

As a result, there is a problem in that the gap between image display surfaces is visually recognized between adjacent image display units in a case where one image is displayed on a plurality of image display units.

An object of the present invention is to solve the above-described problem of the related art and to provide an image display device that includes a plurality of image display units and is capable of reducing an interval between display screens of adjacent image display units.

In order to solve the above-described problem, the present invention has the following configurations.

[1] An image display device comprising: a plurality of image display units; and polarizers disposed on image display surface sides of the image display units, in which the image display units are disposed adjacent to each other, and the polarizers contain a dichroic substance and a liquid crystal compound.

[2] The image display device according to [1], in which an interval between the image display surfaces of the adjacent image display units is 1 mm or less.

[3] The image display device according to [1] or [2], in which the polarizers satisfy the following expression after being held in an environment of a temperature of 85° C. and a humidity of 85% RH for 100 hours,

|Te−Tc|<2.0[%]
Te: a transmittance [%] of each polarizer at a position separated from an end portion of the image display unit by 1 mm,
Tc: a transmittance [%] of each polarizer at a position separated from the end portion of the image display unit by 10 mm.

[4] The image display device according to any one of [1] to [3], in which the image display device is bendable between the adjacent image display units.

[5] The image display device according to any one of [1] to [4], in which the image display units are arranged one-dimensionally or two-dimensionally.

[6] The image display device according to [5], in which the image display units are separable.

[7] The image display device according to any one of [1] to [6], in which the image display units are organic electroluminescence display elements.

[8] The image display device according to any one of [1] to [6], in which the image display units are LED display elements or micro-LED display elements.

According to the present invention, the image display device including a plurality of image display units is capable of reducing an interval between display screens of adjacent image display units.

### BRIEF DESCRIPTION OF THE DRAWINGS

FIG. 1 is a view conceptually illustrating an example of an image display device of the present invention.

FIG. 2 is a view conceptually illustrating an example of a bonding portion of an image display unit in the image display device illustrated in FIG. 1.

FIG. 3 is a view conceptually illustrating another example of the image display device of the present invention.

FIG. 4 is a conceptual view for describing the image display device of the present invention.

FIG. 5 is a conceptual view for describing an image display device of the related art.

### DESCRIPTION OF THE PREFERRED EMBODIMENTS

Hereinafter, an image display device according to an embodiment of the present invention will be described in detail based on suitable examples illustrated in the accompanying drawings.

The description of the constituent elements described below may be made based on representative embodiments of the present invention, but the present invention is not limited to the following embodiments.

Further, all the drawings described below are views conceptually illustrating the present invention in order to describe the present invention. Therefore, the size, the thickness, the length, the positional relationship, and the like of each member do not necessarily match the actual ones.

In the present specification, a numerical range shown using “to” indicates a range including numerical values described before and after “to” as a lower limit and an upper limit.

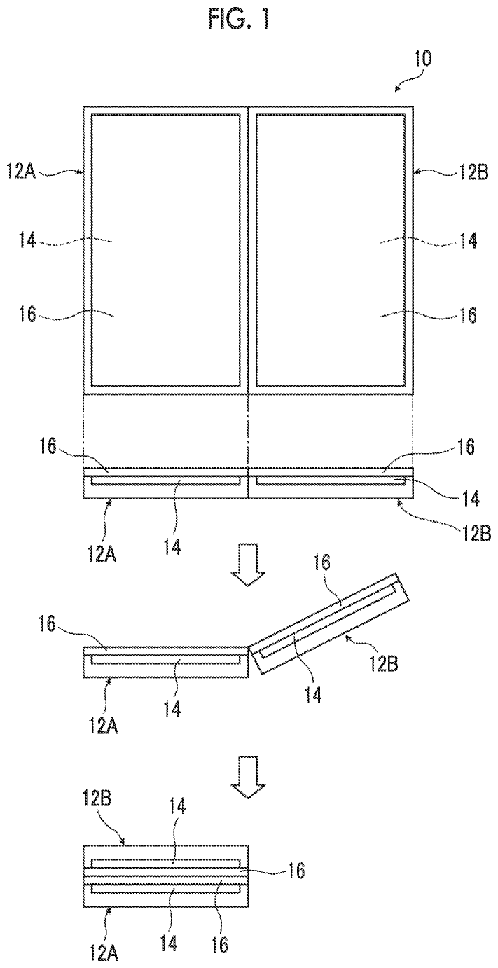

FIG. 1 is a view conceptually illustrating an example of an image display device according to the embodiment of the present invention.

The image display device according to the embodiment of the present invention includes a plurality (two or more) image display units disposed adjacent to each other and polarizers disposed on image display surface sides of the image display units.

The image display device 10 illustrated in FIG. 1 includes a first image display unit 12A and a second image display unit 12B that are disposed adjacent to each other. Both the first image display unit 12A and the second image display unit 12B include an image display surface 14 and a polarizer 16 disposed on the image display surface 14 side.

That is, the first image display unit 12A and the second image display unit 12B are basically image display elements identical to each other.

In the image display device according to the embodiment of the present invention, the polarizer 16 disposed on the image display surface 14 side, that is, on a visual recognition surface side of the image display surface 14 is a linear polarizer. Here, in the present invention, the polarizer 16 contains a dichroic substance and a liquid crystal compound.

In the image display device according to the embodiment of the present invention, the interval between the image display surfaces of adjacent image display units in the image display device including a plurality of image display units can be reduced by using the polarizer 16 containing a dichroic substance and a liquid crystal compound. This point will be described in detail later.

The image display device 10 illustrated in FIG. 1 can be bent and further folded between the first image display unit 12A and the second image display unit 12B by, for example, folding back the second image display unit 12B.

A method of enabling the image display device 10 to be bent between the first image display unit 12A and the second image display unit 12B is not limited, and various known methods of bendably connecting plate-like materials disposed adjacent to each other between plate-like materials can be used.

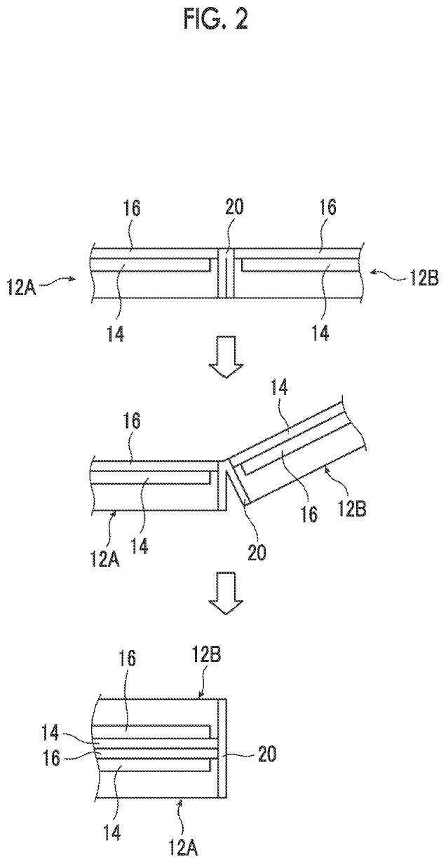

As an example conceptually illustrated in FIG. 2, a method of connecting adjacent end surfaces of two image display units with a belt-like connection member 20 capable of being bent in a lateral direction, a method of using a hinge, or a method of connecting adjacent end surfaces of two image display units with an elastic member may be employed.

Further, as described below, the image display device 10 according to the embodiment of the present invention is capable of reducing the interval between the image display surfaces in the adjacent image display units. Therefore, it is preferable to use a method in which adjacent image display units are not spaced from each other as much as possible, as a method of enabling the image display device 10 to be bent between two image display units.

Further, the image display device may be bent such that the image display surfaces are oriented inside.

Further, in a case where the image display device according to the embodiment of the present invention is made bendable between adjacent image display units, the number of image display units is not limited to two.

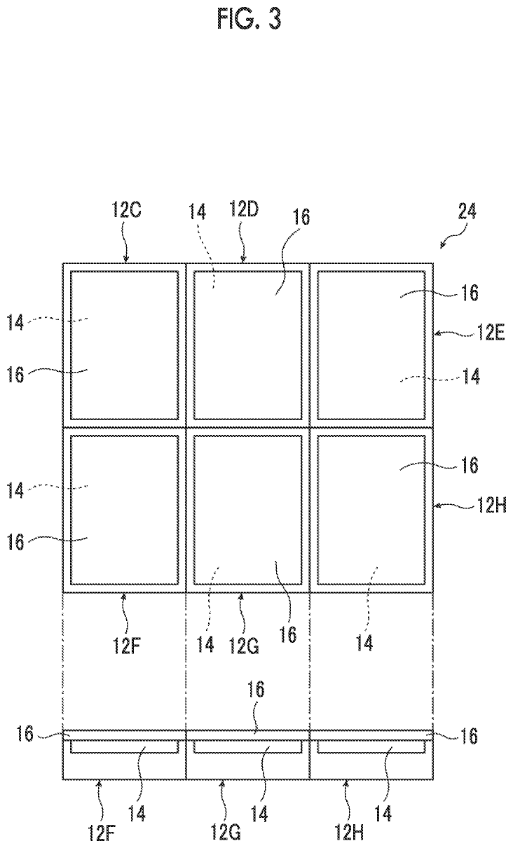

For example, an image display device having six image display units arranged in 2 rows and 3 columns as illustrated in FIG. 3 described below may be made bendable between first to third image display units 12C to 12E and fourth to sixth image display units 12F to 12H. Further, the image display device may be made bendable at two sites, which are one site between the first and fourth image display units 12C and 12F and the second and fifth image display units 12D and 12G and one site between the second and fifth image display units 12D and 12G and the third and sixth image display units 12E and 12H.

FIG. 3 conceptually illustrates another example of the image display device according to the embodiment of the present invention.

The image display device 24 illustrated in FIG. 3 includes six image display units, which are the first image display unit 12C, the second image display unit 12D, the third image display unit 12E, the fourth image display unit 12F, the fifth image display unit 12G, and the sixth image display unit 12H. That is, this aspect is a so-called multi-display in which a plurality of image display units are arranged.

The image display device 24 is formed such that six image display units are arranged in 2 rows and 3 columns.

Similar to the image display units of the image display device 10 illustrated in FIG. 1, all the first image display unit 12C, the second image display unit 12D, the third image display unit 12E, the fourth image display unit 12F, the fifth image display unit 12G, and the sixth image display unit 12H have the image display surface 14 and the polarizer 16 disposed on the image display surface 14 side.

That is, the first image display unit 12C to the sixth image display unit 12H are basically image display elements identical to each other.

Further, in the image display device according to the embodiment of the present invention, the number of image display units is not limited to 6 in the illustrated example, and may be 5 or less or 7 or more.

Further, the arrangement of the image display units is not also limited. Therefore, the image display units may be arranged one-dimensionally or two-dimensionally.

Further, an arrangement method in a case of arranging the image display units two-dimensionally is also not limited. For example, in a case where 12 image display units are arranged, the image display units may be arranged in 2 rows and 6 columns or in 3 rows and 4 columns. In this case, the image display units may be one-dimensionally arranged in 1 row and 12 columns.

In the multi-display as illustrated in FIG. 3, each image display unit may be fixed in an arranged state, but it is preferable that the image display units are individually separable.

A method of separably connecting the image display units is not limited, and various known methods can be used. Examples thereof include a method of using a known jig that detachably engages plate-like materials, a method of providing, on facing side surfaces of adjacent image display units, engaging portions such as irregular portions that are fitted to each other, and a method of fixing facing side surfaces of adjacent image display units using pressure sensitive adhesive tape, a magnet, or the like.

Alternatively, image display units may be detachably provided on a support table (support plate) that supports all the image display units by the above-described methods.

Alternatively, the individual image display units may be separated by fixing the image display units arranged using a frame such as a picture frame with the frame and removing the frame. In a case where the arranged image display units are fixed using a frame, a support plate that supports the arranged image display units such that the image display units are placed on the support may be used in combination as necessary.

In the present invention, the first image display unit 12A and the second image display unit 12B and the first image display unit 12C to the sixth image display unit 12H having the image display surface 14 are not limited, and various known image display elements (image display panels) can be used.

Examples thereof include a liquid crystal display element, an organic EL display element, an LED display element, and a micro-LED display element.

Among these, an organic EL display element, an LED display element, and a micro-LED display element are suitably used.

Further, the image display surface is a region where an image is displayed, that is, a region where pixels for displaying an image are arranged in the image display element.

Further, the image display unit includes, in addition to the image display surface 14 illustrated in the figures, various known members according to the image display device, for example, an optical element such as a wavelength plate, a driver for driving, a control unit of a driver, a backlight unit (liquid crystal display element), and the like, as necessary.

Here, a liquid crystal display element (liquid crystal display panel) has a configuration in which two polarizers having absorption axes orthogonal to each other are provided on both surfaces of a liquid crystal cell having a liquid crystal layer. In a case where the liquid crystal display element is used as the image display unit, the polarizer provided on the emission side (image display surface side) between the two polarizers is the polarizer 16 in the present invention.

Further, an organic EL display element (organic EL display panel), an LED display element (LED display panel), and a micro-LED display element (micro-LED display panel) typically include an antireflection film consisting of a linear polarizer and a ¼λ wavelength plate on the image display surface side. In a case where the organic EL display element, the LED display element, and the micro-LED display element are used as the image display unit, the linear polarizer of the antireflection film is the polarizer 16 in the present invention.

Further, the image display device according to the embodiment of the present invention may include, on the surface of the polarizer 16, layers (films) exhibiting target functions such as a protective layer, a barrier layer, an anti-fingerprint layer, an antireflection layer, a retardation film, a depolarization film, and an anti-scattering film as necessary.

As described above, the image display device according to the embodiment of the present invention includes a plurality of image display units adjacent to each other and the polarizers 16 on the image display surface sides of the image display units. Further, the polarizer 16 is a polarizer containing a dichroic substance and a liquid crystal compound.

In the image display device having a plurality of the image display units disposed adjacent to each other, the interval of the image display surfaces in the adjacent image display units can be reduced because the image display device according to the embodiment of the present invention has the above-described configuration. As a result, according to the present invention, the image display device having a plurality of the image display units disposed adjacent to each other is capable of displaying an image in which gaps between the image display surfaces, that is, joints between the screens are inconspicuous.

As described in JP2018-031884A, in the image display device in which a plurality of image display units are arranged, a liquid crystal display element, an organic EL display element, or the like is used as the image display unit. These image display elements have a polarizer on the image display surface side as described above.

Here, as described in JP2020-056929A, PVA containing iodine is suitably used as a polarizer in an image display element due to a high polarization degree. In the following description, a polarizer formed of PVA will also be referred to as “PVA-based polarizer”.

However, according to the examination conducted by the present inventors, the PVA-based polarizer has poor moisture resistance and deteriorates from an end portion due to moisture absorption. As a result, an end portion of an image display unit formed of the PVA-based polarizer is fading. In particular, deterioration progresses from the end portion, and a fading region is generated over several millimeters from the end portion in a high-humidity and high-temperature environment.

Further, since the PVA-based polarizer is hard and brittle, cracks may occur at an end portion in a case where the PVA-based polarizer is punched to be cut into a desired shape.

Further, the PVA-based polarizer is required to be formed such that a functional layer consisting of a PVA film is thick and protective films are bonded to both surfaces of the functional layer. Therefore, the polarizer is thick, and for example, may be burned over a maximum of approximately 1 mm in a case of being cut with a layer.

Therefore, in the image display element formed of the PVA-based polarizer, it is necessary to take measures, for example, coloring an end portion in black and sufficiently separating an end portion of an image display surface from an end portion of the polarizer so that a display image is not adversely affected by deterioration of the end portion of the polarizer.

Further, in the image display device having image display units disposed adjacent to each other, in a case where the end portion of the polarizer deteriorates, for example, the end portion is colorless and a pure white color is displayed in a case of the liquid crystal display element, and light escapes from the end portion in a case of the organic EL display element. As a result, the gap between the display screens, that is, the joint between the images is conspicuous.

That is, in the image display device formed such that the image display element formed of the PVA-based polarizing element is used as the image display unit and the image display units are disposed adjacent to each other, the end portions of the image display surfaces 14 are required to be largely oriented inward with respect to the end portions of the polarizers 104 in the image display units 100 as conceptually illustrated in FIG. 5. Therefore, in a case where the image display units formed of the PVA-based polarizers are disposed adjacent to each other, an interval d between the image display surfaces 14 in the adjacent image display units 100 increases as illustrated in FIG. 5.

As a result, in a case where an image is displayed by using a plurality of the image display units as one screen, the interval between the image display surface 14 and the image display surface 14, that is, the joint between the screens is widened in the adjacent image display units, and the gap between the image display surfaces is visually recognized.

Meanwhile, in the image display device according to the embodiment of the present invention, a polarizer containing a dichroic substance and a liquid crystal compound is used as the polarizer 16 of the image display unit.

The polarizer has high moisture resistance and is thin because the polarizer is formed by a coating method. Therefore, deterioration of the end portion due to moisture absorption as in the case of the PVA-based polarizer, and occurrence of cracks in the end portion and occurrence of burning accompanied by cutting can be prevented.

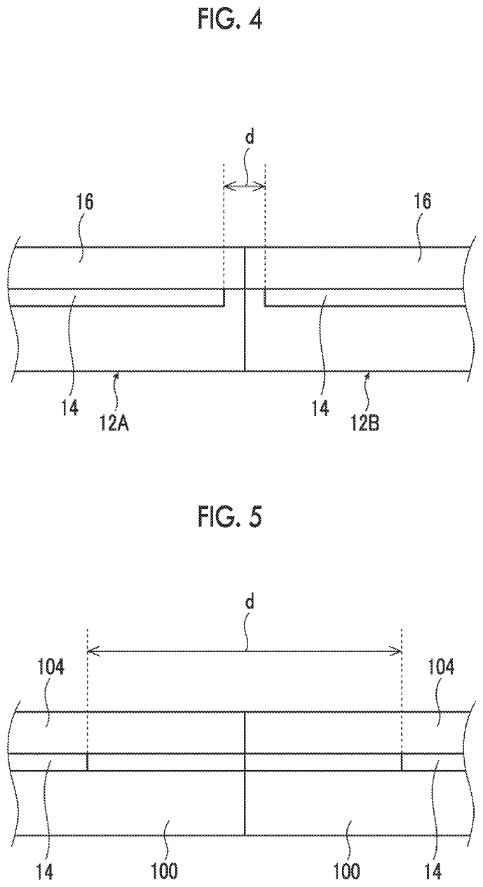

Therefore, in the image display device according to the embodiment of the present invention, the end portion of the image display surface 14 can be set to be at a position as close as possible to the end portion of the polarizer 16 in the image display unit as conceptually illustrating an example of the image display device 10 (FIG. 1) in FIG. 4. Therefore, in the first image display unit 12A and the second image display unit 12B adjacent to each other, the interval d between the image display surfaces 14, that is, the joint between the screens can be significantly reduced as illustrated in FIG. 4.

As a result, according to the present invention, in the image display device having a plurality of image display units disposed adjacent to each other, an image in which a gap between the image display surfaces is not visually recognized can be displayed in a case where an image is displayed by using the plurality of image display units as one screen.

In the image display device according to the embodiment of the present invention, the interval between the image display surfaces in the adjacent image display units, that is, the interval d in FIG. 4 is not limited, but it is preferable that the interval is narrow.

Specifically, the interval d is preferably 1 mm or less and more preferably 0.2 mm or less.

Further, it is preferable that the interval d is basically narrow, but it is preferable that the interval d matches an interval between pixels in the image display device from the viewpoint of making the interval between the image display surfaces less conspicuous.

In the image display device according to the embodiment of the present invention, the polarizer 16 contains a liquid crystal compound and a dichroic substance. Various known polarizers containing a liquid crystal compound and a dichroic substance can be used as the polarizer 16.

In the polarizer, the dichroic substance is also aligned in a predetermined direction along the alignment of the liquid crystal compound. In particular, it is preferable that the dichroic substance is horizontally aligned.

In the following, first, the material used for forming the polarizer will be described in detail.

(Liquid Crystal Compound)

Both a polymer liquid crystal compound and a low-molecular-weight liquid crystal compound can be used as the liquid crystal compound, and a polymer liquid crystal compound is preferably used from the viewpoint of further increasing the alignment degree of the dichroic sub stance.

Here, “polymer liquid crystal compound” denotes a liquid crystal compound having a repeating unit in the chemical structure.

Here, “low-molecular-weight liquid crystal compound” denotes a liquid crystal compound having no repeating units in the chemical structure.

Examples of the polymer liquid crystal compound include thermotropic liquid crystal polymers described in JP2011-237513A and polymer liquid crystal compounds described in paragraphs [0012] to [0042] of WO2018/199096A.

Examples of the low-molecular-weight liquid crystal compound include liquid crystal compounds described in paragraphs [0072] to [0088] of JP2013-228706A. Among these, a liquid crystal compound exhibiting smectic properties is preferable.

Further, a polymer liquid crystal compound and a low-molecular-weight liquid crystal compound may be used in combination as the liquid crystal compound.

From the viewpoint of further increasing the alignment degree of the dichroic substance, a polymer liquid crystal compound having a repeating unit represented by Formula (1) (hereinafter, also simply referred to as “repeating unit (1)”) is preferable as the liquid crystal compound.

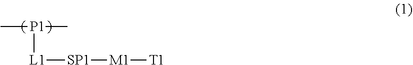

In Formula (1), P1 represents the main chain of the repeating unit, L1 represents a single bond or a divalent linking group, SP1 represents a spacer group, M1 represents a mesogen group, and T1 represents a terminal group.

Examples of the main chain of the repeating unit represented by P1 include groups represented by Formula (P1-A) to Formula (P1-D), among which a group represented by Formula (P1-A) is preferable from the viewpoint of the diversity of monomers as raw materials and the ease of handling.

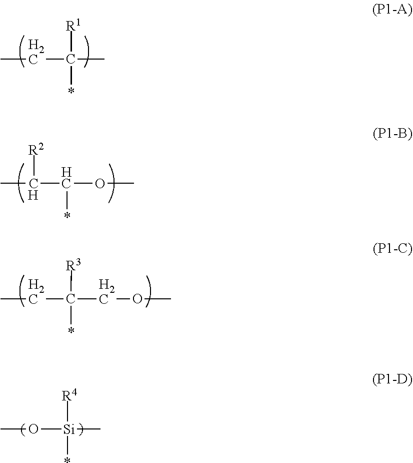

In Formulae (P1-A) to (P1-D), “*” represents a bonding position with respect to L1 in Formula (1).

In Formulae (P1-A) to (P1-D), R¹, R², R³, and R⁴ each independently represent a hydrogen atom, a halogen atom, a cyano group, an alkyl group having 1 to 10 carbon atoms, or an alkoxy group having 1 to 10 carbon atoms. The alkyl group may be a linear or branched alkyl group or an alkyl group having a cyclic structure (cycloalkyl group). Further, the number of carbon atoms of the alkyl group is preferably in a range of 1 to 5.

It is preferable that the group represented by Formula (P1-A) is a unit of a partial structure of poly(meth)acrylic acid ester obtained by polymerization of (meth)acrylic acid ester.

It is preferable that the group represented by Formula (P1-B) is an ethylene glycol unit formed by ring-opening polymerization of an epoxy group of a compound containing the epoxy group.

It is preferable that the group represented by Formula (P1-C) is a propylene glycol unit formed by ring-opening polymerization of an oxetane group of a compound containing the oxetane group.

It is preferable that the group represented by Formula (P1-D) is a siloxane unit of a polysiloxane obtained by polycondensation of a compound containing at least one of an alkoxysilyl group or a silanol group. Here, examples of the compound containing at least one of an alkoxysilyl group or a silanol group include a compound containing a group represented by Formula SiR⁴(OR⁵)₂—. In the formula, R⁴ has the same definition as that for R⁴ in Formula (P1-D), and a plurality of R⁵'s each independently represent a hydrogen atom or an alkyl group having 1 to 10 carbon atoms.

In Formula (1), L1 represents a single bond or a divalent linking group.

Examples of the divalent linking group represented by L1 include —C(O)O—, —O—, —S—, —C(O)NR⁶—, —SO₂—, and —NR⁶R⁷—. In the formulae, R⁶ and R⁷ each independently represent a hydrogen atom or an alkyl group having 1 to 6 carbon atoms which may have a substituent.

In a case where P1 is a group represented by Formula (P1-A), L1 is preferably a group represented by —C(O)O— from the viewpoint that the alignment degree of the dichroic substance is higher.

In a case where P1 is a group represented by Formula (P1-B) to Formula (P1-D), L1 is preferably a single bond from the viewpoint that the alignment degree of the dichroic substance is higher.

In Formula (1), the spacer group represented by SP1 preferably contains at least one structure selected from the group consisting of an oxyethylene structure, an oxypropylene structure, a polysiloxane structure, and a fluorinated alkylene structure, from the viewpoint of easily exhibiting liquid crystallinity, availability of raw materials, and the like.

Here, as the oxyethylene structure represented by SP1, a group represented by *—(CH₂—CH₂O)ₙ₁—* is preferable. In the formula, n1 represents an integer of 1 to 20, and “*” represents a bonding position with respect to L1 or M1 in Formula (1). From the viewpoint that the alignment degree of the dichroic substance is higher, n1 is preferably an integer of 2 to 10, more preferably an integer of 2 to 4, and most preferably 3.

In addition, it is preferable that the oxypropylene structure represented by SP1 is a group represented by *—(CH(CH₃)—CH₂O)ₙ₂—* from the viewpoint of further increasing the alignment degree of the dichroic substance. In the formula, n2 represents an integer of 1 to 3, and “*” represents a bonding position with respect to L1 or M1.

In addition, it is preferable that the polysiloxane structure represented by SP1 is a group represented by *—(Si(CH₃)₂—O)ₙ₃—* from the viewpoint of further increasing the alignment degree of the dichroic substance. In the formula, n3 represents an integer of 6 to 10, and “*” represents a bonding position with respect to L1 or M1.

In addition, it is preferable that the fluorinated alkylene structure represented by SP1 is a group represented by *—(CF₂—CF₂)ₙ₄—* from the viewpoint of further increasing the alignment degree of the dichroic substance. In the formula, n4 represents an integer of 6 to 10, and “*” represents a bonding position with respect to L1 or M1.

In Formula (1), the mesogen group represented by M1 is a group showing a main skeleton of a liquid crystal molecule that contributes to liquid crystal formation. A liquid crystal molecule exhibits liquid crystallinity which is in an intermediate state (mesophase) between a crystal state and an isotropic liquid state. The mesogen group is not particularly limited, and for example, particularly the description on pages 7 to 16 of “Flussige Kristalle in Tabellen II” (VEB Deutsche Verlag fur Grundstoff Industrie, Leipzig, 1984) and particularly the description in Chapter 3 of “Liquid Crystal Handbook” (Maruzen, 2000) edited by Liquid Crystal Handbook Editing Committee can be referred to.

For example, a group having at least one cyclic structure selected from the group consisting of an aromatic hydrocarbon group, a heterocyclic group, and an alicyclic group is preferable as the mesogen group.

From the viewpoint that the alignment degree of the dichroic substance is higher, the mesogen group preferably has an aromatic hydrocarbon group, more preferably 2 to 4 aromatic hydrocarbon groups, and still more preferably 3 aromatic hydrocarbon groups.

From the viewpoint of exhibiting liquid crystallinity, adjustment of liquid crystal phase transition temperature, availability of raw materials, and synthetic suitability, and from the viewpoint that the alignment degree of the dichroic substance is higher, the mesogen group is preferably a group represented by Formula (M1-A) or Formula (M1-B) and more preferably a group represented by Formula (M1-B).

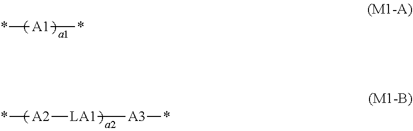

In Formula (M1-A), A1 represents a divalent group selected from the group consisting of an aromatic hydrocarbon group, a heterocyclic group, and an alicyclic group. These groups may be substituted with an alkyl group, a fluorinated alkyl group, an alkoxy group, or a substituent.

It is preferable that the divalent group represented by A1 is a 4- to 6-membered ring. Further, the divalent group represented by A1 may be a monocycle or a fused ring.

Further, “*” represents a bonding position with respect to SP1 or T1.

Examples of the divalent aromatic hydrocarbon group represented by A1 include a phenylene group, a naphthylene group, a fluorene-diyl group, an anthracene-diyl group, and a tetracene-diyl group, among which a phenylene group or a naphthylene group is preferable and a phenylene group is more preferable, from the viewpoint of design diversity of a mesogen skeleton, availability of raw materials, and the like.

The divalent heterocyclic group represented by A1 may be either aromatic or non-aromatic, and is preferably a divalent aromatic heterocyclic group from the viewpoint that the alignment degree of the dichroic substance is higher.

The atoms other than carbon constituting the divalent aromatic heterocyclic group include a nitrogen atom, a sulfur atom, and an oxygen atom. In a case where the aromatic heterocyclic group has a plurality of atoms constituting a ring other than carbon, these may be the same as or different from each other.

Examples of the divalent aromatic heterocyclic group include a pyridylene group (a pyridine-diyl group), a pyridazine-diyl group, an imidazole-diyl group, a thienylene group (a thiophene-diyl group), a quinolylene group (a quinoline-diyl group), an isoquinolylene group (an isoquinoline-diyl group), an oxazole-diyl group, a thiazole-diyl group, an oxadiazole-diyl group, a benzothiazole-diyl group, a benzothiadiazole-diyl group, a phthalimide-diyl group, a thienothiazole-diyl group, a thiazolothiazole-diyl group, a thienothiophene-diyl group, and a thienoxazole-diyl group.

Examples of the divalent alicyclic group represented by A1 include a cyclopentylene group and a cyclohexylene group.

In Formula (M1-A), a1 represents an integer of 1 to 10. In a case where a1 represents 2 or greater, a plurality of A1's may be the same as or different from each other.

In Formula (M1-B), A2 and A3 each independently represent a divalent group selected from the group consisting of an aromatic hydrocarbon group, a heterocyclic group, and an alicyclic group. Specific examples and preferred embodiments of A2 and A3 are the same as those for A1 in Formula (M1-A), and thus description thereof will not be repeated.

In Formula (M1-B), a2 represents an integer of 1 to 10. In a case where a2 represents 2 or greater, a plurality of A2's may be the same as or different from each other, a plurality of A3's may be the same as or different from each other, and a plurality of LA1's may be the same as or different from each other. From the viewpoint that the alignment degree of the dichroic substance is higher, a2 is preferably an integer of 2 or greater and more preferably 2.

In Formula (M1-B), in a case where a2 represents 1, LA1 represents a divalent linking group. In a case where a2 represents 2 or greater, a plurality of LA1's each independently represent a single bond or a divalent linking group, and at least one of the plurality of LA1's is a divalent linking group. In a case where a2 is 2, it is preferable that one of the two LA1's is a divalent linking group and the other of the two LA1's is a single bond, from the viewpoint that the alignment degree of the dichroic substance is higher.

In Formula (M1-B), examples of the divalent linking group represented by LA1 include —O—, —(CH₂)_{g}—, —(CF₂)_{g}—, —Si(CH₃)₂—, —(Si)(CH₃)₂O)_{g}—, —(OSi(CH₃)₂)_{g}— (g represents an integer of 1 to 10), —N(Z)—, —C(Z)═C(Z′)—, —C(Z)═N—, —N═C(Z)—, —C(Z)₂—C(Z′)₂—, —C(O)—, —OC(O)—, —C(O)O—, —O—C(O)O—, —N(Z)C(O)—, —C(O)N(Z)—, —C(Z)═C(Z′)—C(O)O—, —O—C(O)—C(Z)═C(Z′)—, —C(Z)═N—, —N═C(Z)—, —C(Z)═C(Z′)—C(O)N(Z″)—, —N(Z″)—C(O)—C(Z)═C(Z″)—, —C(Z)═C(Z′)—C(O)—S—, —S—C(O)—C(Z)═C(Z)—, and —C(Z)═N—N═C(Z′)— (Z, Z′, and Z″ each independently represent a hydrogen atom, a C1-C4 alkyl group, a cycloalkyl group, an aryl group, a cyano group, or a halogen atom), —C≡C—, —N═N—, —S—, —S(O)—, —S(O)(O)—, —(O)S(O)O—, —O(O)S(O)O—, —SC(O)—, and —C(O)S—. Above all, the divalent linking group represented by LA1 is preferably —C(O)O— from the viewpoint that the alignment degree of the dichroic substance is higher. LA1 may represent a group obtained by combining two or more of these groups.

In Formula (1), examples of the terminal group represented by T1 include a hydrogen atom, a halogen atom, a cyano group, a nitro group, a hydroxy group, an alkyl group having 1 to 10 carbon atoms, an alkoxy group having 1 to 10 carbon atoms, an alkylthio group having 1 to 10 carbon atoms, an alkoxycarbonyloxy group having 1 to 10 carbon atoms, an alkoxycarbonyl group having 1 to 10 carbon atoms (ROC(O)— where R is an alkyl group), an acyloxy group having 1 to 10 carbon atoms, an acylamino group having 1 to 10 carbon atoms, an alkoxycarbonylamino group having 1 to 10 carbon atoms, a sulfonylamino group having 1 to 10 carbon atoms, a sulfamoyl group having 1 to 10 carbon atoms, a carbamoyl group having 1 to 10 carbon atoms, a sulfinyl group having 1 to 10 carbon atoms, a ureide group having 1 to carbon atoms, and a (meth)acryloyloxy group-containing group. Examples of the (meth)acryloyloxy group-containing group include a group represented by -L-A (L represents a single bond or a linking group, specific examples of the linking group are the same as those for L1 and SP1 described above, and A represents a (meth)acryloyloxy group).

From the viewpoint that the alignment degree of the dichroic substance is higher, T1 is preferably an alkoxy group having 1 to 10 carbon atoms, more preferably an alkoxy group having 1 to 5 carbon atoms, and still more preferably a methoxy group.

These terminal groups may be further substituted with these groups or the polymerizable groups described in JP2010-244038A.

T1 is preferably a polymerizable group from the viewpoint that the adhesiveness between the polarizer and the optically anisotropic layer can be improved and the cohesive force as a film can be improved.

The polymerizable group is preferably a radically polymerizable group or a cationically polymerizable group.

As the radically polymerizable group, a generally known radically polymerizable group can be used, and an acryloyl group or a methacryloyl group is preferable. In this case, an acryloyl group is generally known to have a high polymerization rate and therefore the acryloyl group is preferable from the viewpoint of improving productivity, but a methacryloyl group can also be used as the polymerizable group.

A generally known cationically polymerizable group can be used as the cationically polymerizable group, and examples thereof include an alicyclic ether group, a cyclic acetal group, a cyclic lactone group, a cyclic thioether group, a spiroorthoester group, and a vinyloxy group. Among these groups, an alicyclic ether group or a vinyloxy group is preferable, and an epoxy group, an oxetanyl group, or a vinyloxy group is more preferable.

The weight-average molecular weight (Mw) of the high molecular weight liquid crystal compound containing the repeating unit represented by Formula (1) is preferably 1,000 to 500,000 and more preferably 2,000 to 300,000. In a case where the Mw of the polymer liquid crystal compound is in the above-described range, the polymer liquid crystal compound is easily handled.

In particular, from the viewpoint of suppressing the occurrence of cracks in a case of being coated, the weight-average molecular weight (Mw) of the high molecular weight liquid crystal compound is preferably 10,000 or more and more preferably 10,000 to 300,000.

In addition, from the viewpoint of the temperature latitude of the alignment degree, the weight-average molecular weight (Mw) of the polymer liquid crystal compound is preferably less than 10,000 and more preferably 2,000 or greater and less than 10,000.

Here, the weight-average molecular weight and the number average molecular weight in the present invention are values measured by the gel permeation chromatography (GPC) method.
Solvent (eluent): N-methylpyrrolidone
Device name: TOSOH HLC-8220GPC
Column: Connect and use three of TOSOH TSKgel Super AWM-H (6 mm×15 cm)
Column temperature: 25° C.
Sample concentration: 0.1% by mass
Flow rate: 0.35 mL/min
Calibration curve: TSK standard polystyrene (manufactured by TOSOH Corporation), calibration curves of 7 samples with Mw of 2,800,000 to 1,050 (Mw/Mn=1.03 to 1.06) are used.

The content of the liquid crystal compound is preferably 50% by mass or greater and more preferably 70% by mass or greater with respect to the total mass of the polarizer. The upper limit of the content of the second liquid crystal compound is not particularly limited, and is often 95% by mass or less.

(Dichroic Substance)

The dichroic substance is not particularly limited, and conventionally known dichroic substances (dichroic coloring agents) can be used including a visible light absorbing substance (a dichroic coloring agent), a luminescent substance (a fluorescent substance and a phosphorescent substance), an ultraviolet absorbing substance, an infrared absorbing substance, a nonlinear optical substance, a carbon nanotube, and an inorganic substance (for example, a quantum rod).

Examples of the dichroic substance include those described in paragraphs [0067] to [0071] of JP2013-228706A, paragraphs [0008] to [0026] of JP2013-227532A, paragraphs [0008] to [0015] of JP2013-209367A, paragraphs [0045] to [0058] of JP2013-014883A, paragraphs [0012] to [0029] of JP2013-109090A, paragraphs [0009] to [0017] of JP2013-101328A, paragraphs [0051] to [0065] of JP2013-037353A, paragraphs [0049] to [0076] of JP2012-063387A, paragraphs [0016] to [0018] of JP1999-305036A (JP-H11-305036A), paragraphs [0009] to [0011] of JP2001-133630A, paragraphs [0030] to [0169] of JP2011-215337A, paragraphs [0017] to [0069] of JP2010-106242A, paragraphs [0011] to [0025] of JP2010-215846A, paragraphs [0074] to [0246] of JP2011-048311A, paragraphs [0013] to [0133] of JP2011-213610A, paragraphs [0074] to [0246] of JP2011-237513A, paragraphs [0005] to [0051] of JP2016-006502A, paragraphs [0005] to [0041] of WO2016/060173A, paragraphs [0008] to [0062] of WO2016/136561A, paragraphs [0014] to [0033] of WO2017/154835A, paragraphs [0014] to [0033] of WO2017/154695A, paragraphs [0013] to [0037] of WO2017/195833A, and paragraphs [0014] to [0034] of WO2018/164252A.

In the present invention, two or more dichroic substances may be used in combination. For example, from the viewpoint of making the resulting polarizer closer to black, it is preferable to use at least one dichroic substance having a maximum absorption wavelength in a wavelength range of 370 nm or longer and shorter than 500 nm and at least one dichroic substance having a maximum absorption wavelength in a wavelength range of 500 nm or longer and shorter than 700 nm in combination.

The dichroic substance may contain a crosslinkable group.

Examples of the crosslinkable group include a (meth)acryloyl group, an epoxy group, an oxetanyl group, and a styryl group. Among these, a (meth)acryloyl group is preferable.

The content of the dichroic substance is preferably 2 to 80 parts by mass and more preferably 5 to 30 parts by mass with respect to 100 parts by mass of the liquid crystal compound.

(Method for Producing Polarizer)

A method of producing the polarizer is not particularly limited, and examples thereof include a method of using a composition for forming a polarizer containing a liquid crystal compound and a dichroic substance. Specifically, a method of coating a predetermined support with the composition for forming a polarizer to form a coating film and aligning liquid crystal components in the coating film is preferable.

Further, the liquid crystal component is a component that also includes a dichroic substance having liquid crystallinity in addition to the above-described liquid crystal compound, in a case where the above-described dichroic substance has liquid crystallinity.

The liquid crystal compound and the dichroic substance contained in the composition for forming a polarizer are as described above.

The composition for forming a polarizer may contain other components in addition to the liquid crystal compound and the dichroic substance described above.

The composition for forming a polarizer preferably contains a polymerization initiator.

The polymerization initiator is not particularly limited, but a compound having photosensitivity, that is, a photopolymerization initiator is preferable.

As the photopolymerization initiator, various compounds can be used without any particular limitation. Examples of the photopolymerization initiator include α-carbonyl compounds (U.S. Pat. Nos. 2,367,661A and 2,367,670A), acyloin ethers (U.S. Pat. No. 2,448,828A), α-hydrocarbon-substituted aromatic acyloin compounds (U.S. Pat. No. 2,722,512A), polynuclear quinone compounds (U.S. Pat. Nos. 3,046,127A and 2,951,758A), combinations of triarylimidazole dimers with p-aminophenyl ketones (U.S. Pat. No. 3,549,367A), acridine and phenazine compounds (JP1985-105667A (JP-S60-105667A) and U.S. Pat. No. 4,239,850A), oxadiazole compounds (U.S. Pat. No. 4,212,970A), o-acyl oxime compounds (paragraph [0065] of JP2016-027384A), and acylphosphine oxide compounds (JP1988-040799B (JP-S63-040799B), JP1993-029234B (JP-H05-029234B), JP1998-095788A (JP-H10-095788A), and JP1998-029997A (JP-H10-029997A)).

In a case where the composition for forming a polarizer contains a polymerization initiator, the content of the polymerization initiator is preferably 0.01 to 30 parts by mass and more preferably 0.1 to 15 parts by mass with respect to a total of 100 parts by mass of the dichroic substance and the liquid crystal compound.

The composition for forming a polarizer preferably contains a surfactant.

In a case where the liquid crystal composition contains a surfactant, the smoothness of the coated surface is improved, the alignment degree is further improved, and cissing and unevenness are suppressed so that the in-plane uniformity is expected to be improved.

The surfactant is preferably a compound that makes the dichroic substance and the liquid crystal compound horizontal on the coating surface side, examples of which include the compounds described in paragraphs [0155] to [0170] of WO2016/009648A and the compounds (horizontal alignment agents) described in paragraphs [0253] to [0293] of JP2011-237513A.

In a case where the composition for forming a polarizer contains a surfactant, the content of the surfactant is preferably 0.001 to 5 parts by mass and more preferably 0.01 to 3 parts by mass with respect to a total of 100 parts by mass of the dichroic substance and the liquid crystal compound.

From the viewpoint of workability, the composition for forming a polarizer preferably contains a solvent.

Examples of the solvent include organic solvents such as ketones, ethers, aliphatic hydrocarbons, alicyclic hydrocarbons, aromatic hydrocarbons, carbon halides, esters, alcohols, cellosolves, cellosolve acetates, sulfoxides, amides, and heterocyclic compounds; and water. These solvents may be used alone or in combination of two or more kinds thereof.

In a case where the composition for forming a polarizer contains a solvent, the content of the solvent is preferably 80% to 99% by mass and more preferably 83% to 97% by mass with respect to the total mass of the composition for forming a polarizer.

The support onto which the composition for forming a polarizer is applied is not particularly limited. The support will be described in detail later.

The support may have an alignment layer on a surface thereof.

An alignment film can be formed by a method such as a rubbing treatment performed on a film surface of an organic compound (preferably a polymer), oblique vapor deposition of an inorganic compound, formation of a layer having microgrooves, or accumulation of an organic compound (such as w-tricosanoic acid, dioctadecylmethylammonium chloride, or methyl stearate) using a Langmuir-Blodgett method (LB film).

The alignment layer is preferably an alignment film formed by a rubbing treatment or a photo-alignment film formed by light irradiation.

A photo-alignment compound contained in the photo-alignment film may be, for example, a known material. A photosensitive compound having a photoreactive group in which at least one of dimerization or isomerization occurs by the action of light is preferably used as the photo-alignment compound.

In addition, the composition for forming a polarizer may be applied onto an optically anisotropic layer which will be described later, in which case the optically anisotropic layer functions as an alignment film.

The method of applying the composition for forming a polarizer is not particularly limited, and includes a curtain coating method, a dip coating method, a spin coating method, a printing coating method, a spray coating method, a slot coating method, a roll coating method, a slide coating method, a blade coating method, a gravure coating method, and a wire bar coating method.

A method of aligning the liquid crystalline component in the coating film is not particularly limited, and is preferably a heat treatment.

From the viewpoint of manufacturing suitability, the heat temperature is preferably in a range of 10° C. to 250° C. and more preferably in a range of 25° C. to 190° C. Further, the heating time is preferably in a range of 1 to 300 seconds and more preferably in a range of 1 to 60 seconds.

A cooling treatment may be carried out after the heat treatment, if necessary. The cooling treatment is a treatment of cooling the coating film after being heated to room temperature (20° C. to 25° C.). Thereby, the alignment of the liquid crystalline component contained in the coating film can be fixed. The cooling means is not particularly limited and the cooling can be carried out by a known method.

In addition, if necessary, a curing treatment may be carried out after the liquid crystalline component is aligned.

In a case where the polarizer contains a crosslinkable group (polymerizable group), the curing treatment is carried out by heating and/or light irradiation (exposure to light).

The thickness of the polarizer is not particularly limited, and is preferably 100 to 8,000 nm and more preferably 300 to 5,000 nm.

Further, the thickness of the polarizer denotes an average thickness of the polarizer. The average thickness is acquired by measuring the thicknesses of the polarizer at any five or more sites and arithmetically averaging the measured values.

In the image display device according to the embodiment of the present invention in which image display units including the polarizers 16 containing a liquid crystal compound and a dichroic substance are disposed adjacent to each other, it is preferable that the polarizers 16 have high heat resistance and moisture resistance.

Specifically, it is preferable that a transmittance Te [%] of the polarizer 16 at a position spaced from the end portion of the image display unit by 1 mm and a transmittance Tc [%] of the polarizer 16 at a position spaced from the end portion of the image display unit by 10 mm after the image display device according to the embodiment of the present invention is held in an environment of a temperature of 85° C. and a humidity of 85% RH for 100 hours satisfy the following expression.

|Te−Tc|<2.0(%)

In a case where the polarizer 16 satisfies the expression, deterioration of the polarizer 16 in a high-temperature and high-humidity environment can be more suitably prevented, and deterioration of the image quality of a display image due to the deterioration of the polarizer 16 can be more suitably prevented.

In the image display device according to the embodiment of the present invention, it is preferable that the directions of the absorption axes of the polarizers 16 of the image display units are the same as each other.

The display image in all the image display units can be properly observed by setting all the directions of the absorption axes of the polarizers 16 of the image display units in the image display device having a plurality of image display units to be the same as each other, for example, even in a case where the image is observed by wearing polarized sunglasses.

In particular, in the bendable image display device 10 as illustrated in FIG. 1, it is preferable that the directions of the absorption axes of the polarizers 16 are set to be parallel or orthogonal to the bending line.

In the bendable image display device 10 as described in FIG. 1, the image may be observed in a state where the image display units are bent at, for example, 90° without being made planar. By setting the directions of the absorption axes of the polarizers 16 to be parallel or orthogonal to the bending line, degradation of visibility due to reflection of light, which has been emitted from one image display unit, on another image display unit can be prevented even in a case where the image is observed in a state where the image display units are bent.

The image display device according to the embodiment of the present invention has been described above in detail, but the present invention is not limited to the above-described examples, and various improvements and changes may be made without departing from the scope of the present invention.

### EXAMPLES

Hereinafter, the present invention will be described in more detail based on examples. Materials, used amounts, ratios, treatment contents, treatment procedures, and the like shown in the following examples are able to be properly changed as long as the changes do not depart from the gist of the present invention. Therefore, the scope of the present invention should not be limitatively interpreted by the following examples.

### Example 1

[Preparation of Transparent Support]

<Preparation of Core Layer Cellulose Acylate Dope>

The following composition was put into a mixing tank and stirred to dissolve each component, thereby preparing a cellulose acetate solution used as a core layer cellulose acylate dope.

Core Layer Cellulose Acylate Dope
Cellulose acetate having acetyl substitution degree of 2.88: 100 parts by mass
Polyester compound B described in example of JP2015-227955A: 12 parts by mass
Compound F shown below: 2 parts by mass
Methylene chloride (first solvent): 430 parts by mass
Methanol (second solvent): 64 parts by mass

Compound F

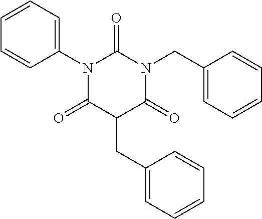 [SMILES: O=C1C(Cc2ccccc2)C(=O)N(c2ccccc2)C(=O)N1Cc1ccccc1]

<Preparation of Outer Layer Cellulose Acylate Dope>

10 parts by mass of the following matting agent solution was added to 90 parts by mass of the above-described core layer cellulose acylate dope, thereby preparing a cellulose acetate solution used as an outer layer cellulose acylate dope.

Matting agent solution

Silica particles with average particle size of 20 nm (AEROSIL R972,
manufactured by NIPPON AEROSIL CO., LTD.): 2 parts by mass
Methylene chloride (first solvent): 76 parts by mass
Methanol (second solvent): 11 parts by mass
Core layer cellulose acylate dope described above: 1 parts by mass

<Preparation of Cellulose Acylate Film 1>

The core layer cellulose acylate dope and the outer layer cellulose acylate dope were filtered through filter paper with an average pore diameter of 34 μm and a sintered metal filter with an average pore diameter of 10 μm. Thereafter, the core layer cellulose acylate dope and the outer layer cellulose acylate dopes on both sides thereof were cast simultaneously on a drum at 20° C. from a casting port in three layers, using a band casting machine.

Next, the film was peeled off in a state where the solvent content was approximately 20% by mass, both ends of the film in the width direction were fixed by tenter clips, and the film was dried while being stretched at a stretching ratio of 1.1 times in the lateral direction.

Thereafter, the film was transported between rolls of a heat treatment device and further dried, thereby preparing an optical film (transparent support) having a thickness of 40 μm. This optical film will be referred to as a cellulose acylate film 1.

[Formation of Photo-Alignment Film PA1]

The cellulose acylate film 1 (support) was continuously coated with the following coating solution PA1 for forming a photo-alignment film using a wire bar. The support on which the coating film was formed was dried with hot air at 140° C. for 120 seconds. Next, the coating film was irradiated with polarized ultraviolet rays (10 mJ/cm², using an ultra-high pressure mercury lamp) to form a photo-alignment film PA1, thereby obtaining a triacetyl cellulose (TAC) film with a photo-alignment film. The film thickness of the photo-alignment film PA1 was 0.5 μm.

Coating solution PA1 for forming photo-alignment film
Polymer PA-1 shown below: 100.00 parts by mass
Acid generator PAG-1 shown below: 8.25 parts by mass
Stabilizer DIPEA shown below: 0.6 parts by mass
Xylene: 1126.60 parts by mass
Methyl isobutyl ketone: 125.18 parts by mass
Polymer PA-1 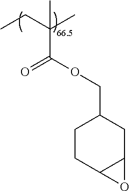 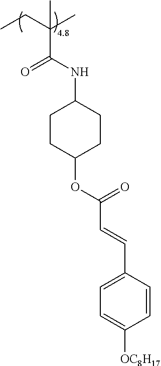 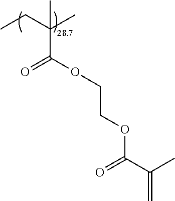
Acid generator PAG-1 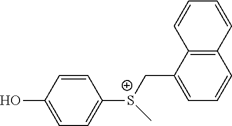 [SMILES: C[S+](Cc1cccc2ccccc12)c1ccc(O)cc1] 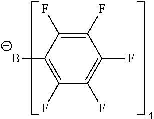
Stabilizer DIPEA

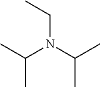

[Preparation of Light Absorption Anisotropic Film P1]

A coating layer P1 was formed by continuously coating the obtained photo-alignment film PA1 with a composition P1 for forming a light absorption anisotropic film with the following composition using a #20 wire bar.

Next, the coating layer P1 was heated at 140° C. for 15 seconds, and the coating layer P1 was cooled to room temperature (23° C.).

Next, the coating layer was heated at 75° C. for 60 seconds and cooled to room temperature again.

Next, the coating layer P1 was irradiated with ultraviolet light using an LED lamp (central wavelength of 365 nm) for 2 seconds under an irradiation condition of an illuminance of 200 mW/cm², thereby preparing a light absorption anisotropic film P1 on the alignment layer PA1. The transmittance of the light absorption anisotropic film in a wavelength range of 280 nm or greater and 780 nm or less was measured with a spectrophotometer, and the average transmittance of visible light was 42%.

Composition of composition P1 for forming light absorption anisotropic film
First dichroic substance C-1 (λmax of 570 nm) shown below: 0.65 parts by mass
Second dichroic substance M-1 (λmax of 466 nm) shown below: 0.15 parts by mass
Third dichroic substance Y-1 (λmax of 417 nm) shown below: 0.52 parts by mass
Liquid crystal compound L-1 shown below: 2.50 parts by mass
Liquid crystal compound L-2 shown below: 1.50 parts by mass
Polymerization initiator IRGACURE OXE-02 (manufactured by BASF SE): 0.17 parts by mass
Surfactant F-1 shown below: 0.01 parts by mass
Cyclopentanone: 46.07 parts by mass
Tetrahydrofuran: 46.07 parts by mass
Benzyl alcohol: 2.36 parts by mass
Dichroic substance C-1 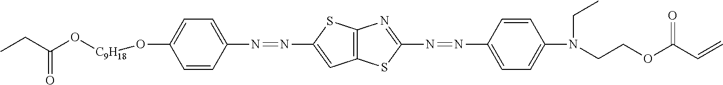
Dichroic substance M-1 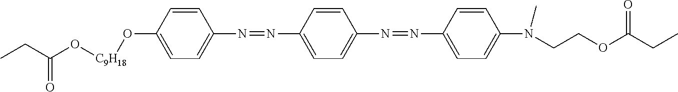
Dichroic substance Y-1 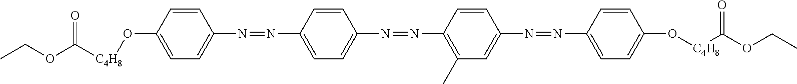
Liquid crystal compound L-1 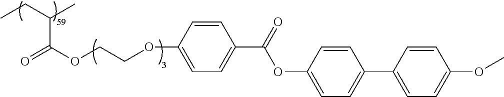 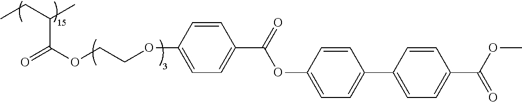 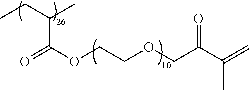
Liquid crystal compound L-2 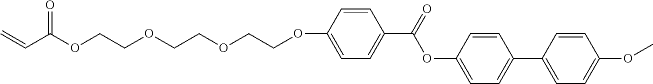 [SMILES: C=CC(=O)OCCOCCOCCOc1ccc(C(=O)Oc2ccc(-c3ccc(OC)cc3)cc2)cc1]
Surfactant F-1

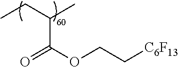

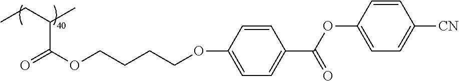

[Formation of Barrier Layer B1]

The light absorption anisotropic film P1 was continuously coated with a coating solution B1 having the following composition with a wire bar. Thereafter, the film was dried with hot air at 80° C. for 5 minutes, thereby obtaining a laminate X1 on which the barrier layer B1 consisting of polyvinyl alcohol (PVA) with a thickness of 1.0 μm was formed, that is, a polarizer POL1 in which the cellulose acylate film 1 (transparent support), the photo-alignment film PA1, the light absorption anisotropic film P1, and the barrier layer B1 were provided adjacent to each other in this order.

Composition of coating solution B1 for forming barrier layer
Modified polyvinyl alcohol shown below: 3.80 parts by mass
Initiator Irg2959: 0.20 parts by mass
Water: 70 parts by mass
Methanol: 30 parts by mass
Modified polyvinyl alcohol

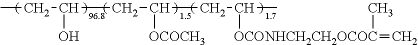

<Preparation of Image Display Device>

A transparent film (polymethyl methacrylate (PMMA)) on which various images were printed was laminated on a surface of a light guide plate “Light face” (manufactured by Dai Nippon Printing Co., Ltd.), and the above-described polarizer POL1 was bonded to the film to obtain an image display unit without a bezel portion.

A plurality of the above-described image display units were prepared, disposed side by side without gaps, and fixed, thereby obtaining an image display device of Example 1.

### Example 2

[Preparation of Light Absorption Anisotropic Film P2]

A coating layer P2 was formed by continuously coating the obtained photo-alignment film PA1 with a composition P2 for forming a light absorption anisotropic film with the following composition using a #4 wire bar.

Next, the coating layer P2 was heated at 120° C. for 60 seconds, and the coating layer P2 was cooled to room temperature (23° C.).

Thereafter, the coating layer was irradiated under an irradiation condition of an illuminance of 28 mW/cm² for 60 seconds using a high-pressure mercury lamp, thereby preparing a light absorption anisotropic film P2 on the alignment film PA1.

Composition P2 for forming light absorption anisotropic layer
Dichroicazo coloring agent compound D6 shown below: 2.7 parts by mass
Dichroicazo coloring agent compound D7 shown below: 2.7 parts by mass
Dichroicazo coloring agent compound D8 shown below: 2.7 parts by mass
Liquid crystal compound M4 shown below: 75.5 parts by mass
Polymerization initiator IRGACURE 819 (manufactured by BASF SE): 0.8 parts by mass
Interface improver F-2 shown below: 0.6 parts by mass
Cyclopentanone: 274.5 parts by mass
Tetrahydrofuran: 640.5 parts by mass
Dichroicazo coloring agent compound D6

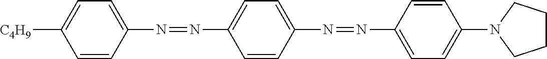

Dichroicazo coloring agent compound D7

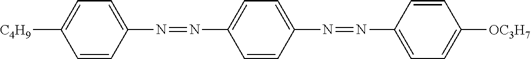

Dichroicazo coloring agent compound D8

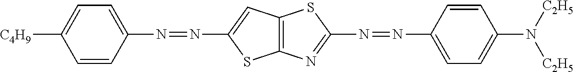

Liquid crystal compound M4 (compound A and compound B were mixed at mixing ratio of 75/25)
(Compound A)

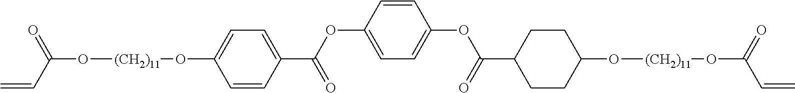

(Compound B)

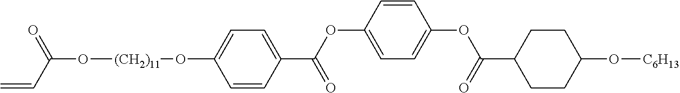

Interface improver F-2

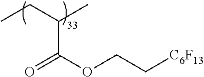

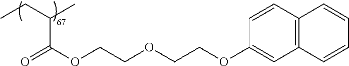

[Formation of Barrier Layer B2]

A barrier layer B2 was formed on the light absorption anisotropic film P2 in the same manner as that for the barrier layer B1 of Example 1, thereby obtaining a polarizer POL2.

<Preparation of Image Display Device>

An image display device of Example 2 was prepared in the same manner as in Example 1 except that the polarizer POL2 was used in place of the above-described polarizer POL1.

### Comparative Example 1

<Preparation of Image Display Device>

An image display device of Comparative Example 1 was prepared in the same manner as in Example 1 except that a typical polarizer POL3 formed of PVA was used in place of the above-described polarizer POL1.

[Evaluation]

The prepared image display device was evaluated as follows.

[Deterioration of Display Performance]

The prepared image display device was placed in a constant-temperature tank at a temperature of 85° C. and a humidity of 85% and held for 100 hours.

The image display device was taken out from the constant-temperature tank and turned on, a gap portion between the image display units was observed from a distance of 50 cm, and deterioration of display performance in the gap portion was evaluated.

<Evaluation Standards for Deterioration of Display Performance>

A: The gap portion was almost not visually recognized, and thus the display performance was satisfactory.

B: The gap portion was brighter than other portions, and the gap was clearly visually recognized.

[Deterioration of End Portion of Polarizer]

The polarizer was peeled off from the image display device taken out from the constant-temperature tank described above, and the transmittance Te [%] of the polarizer at a position spaced from the end portion of the polarizer by 1 mm was measured using a polarimeter Axoscan (manufactured by Axometrics, Inc.). Further, the transmittance Tc [%] of the polarizer at a position spaced from the end portion of the polarizer by 10 mm was measured in the same manner as described above. The deterioration of the end portion of the polarizer was evaluated according to the following equation using the obtained transmittances.

Deterioration of end portion=|Te−Tc|[%]

The evaluation was performed by acquiring an average value of any 10 points.

The results are shown in the table below.

TABLE 1

| | | Evaluation | |
|---|---|---|---|
| | | Deterioration | Deterioration |
| | | of display | of end portion |
| | Polarizer | performance | of polarizer |
| Example 1 | POL 1 (containing liquid | A | 0.8% |
| | crystal compound and | | |
| | dichroic substance) | | |
| Example 2 | POL 2 (containing liquid | A | 1.4% |
| | crystal compound and | | |
| | dichroic substance) | | |
| Comparative | POL 3(typical polarizer | B | 16.4% |
| Example 1 | formed of PVA) | | |

As listed in Table 1, in the image display device of the related art, which had a typical polarizer formed of PVA as the polarizer, the end portion of the polarizer was deteriorated after standing in a high-temperature and high-humidity environment, the gap between adjacent image display units was conspicuous due to the deterioration of the end portion, and thus the display performance was deteriorated.

That is, in the image display device of the related art with a plurality of image display units disposed adjacent to each other, the end portion of the image display surface is required to be disposed largely inside with respect to the end portion of the polarizer in consideration of the deterioration of the end portion of the polarizer due to moisture absorption. Therefore, in the image display device of the related art, the interval between the image display surfaces increases between the adjacent image display units, and thus the gap between the image display surfaces is visually recognized between the adjacent image display units.

On the contrary, the image display device according to the embodiment of the present invention, which is formed of the polarizer containing a liquid crystal compound and a dichroic substance, has less deterioration of the end portion of the polarizer even after standing in a high-temperature and high-humidity environment. As a result, the gap between the adjacent image display units is not conspicuous, that is, the deterioration of the display performance is small.

Therefore, according to the present invention, in the image display device having a plurality of image display units disposed adjacent to each other, the end portion of the image display surface can be brought close to the end portion of the polarizer. Therefore, according to the present invention, it is possible to suppress the gap between the image display surfaces of the adjacent image display units from being visually recognized by reducing the interval between the image display surfaces of the adjacent image display units.

As shown in the results described above, the effects of the present invention are apparent.

The present invention can be suitably used for a foldable image display device, a multi-display, and the like.

### EXPLANATION OF REFERENCES

10, 24: image display device
12A: first image display unit
12B: second image display unit
12C: first image display unit
12D: second image display unit
12E: third image display unit
12F: fourth image display unit
12G: fifth image display unit
12H: sixth image display unit
14: image display surface
16, 104: polarizer
20: connection member
100: image display unit
d: interval

What is claimed is:

1. An image display device comprising:
a plurality of image display units; and
polarizers disposed on image display surface sides of the image display units,
wherein the image display units are disposed adjacent to each other, and
the polarizers contain a dichroic substance and a liquid crystal compound.

2. The image display device according to claim 1,
wherein an interval between the image display surfaces of the adjacent image display units is 1 mm or less.

3. The image display device according to claim 1,
wherein the polarizers satisfy the following expression after being held in an environment of a temperature of 85° C. and a humidity of 85% RH for 100 hours,

|Te−Tc|<2.0[%]
Te: a transmittance [%] of each polarizer at a position separated from an end portion of the image display unit by 1 mm,
Tc: a transmittance [%] of each polarizer at a position separated from the end portion of the image display unit by 10 mm.

4. The image display device according to claim 1,
wherein the image display device is bendable between the adjacent image display units.

5. The image display device according to claim 1,
wherein the image display units are arranged one-dimensionally or two-dimensionally.

6. The image display device according to claim 5,
wherein the image display units are separable.

7. The image display device according to claim 1,
wherein the image display units are organic electroluminescence display elements.

8. The image display device according to claim 1,
wherein the image display units are LED display elements or micro-LED display elements.

9. The image display device according to claim 2,
wherein the polarizers satisfy the following expression after being held in an environment of a temperature of 85° C. and a humidity of 85% RH for 100 hours,

|Te−Tc|<2.0[%]
Te: a transmittance [%] of each polarizer at a position separated from an end portion of the image display unit by 1 mm,
Tc: a transmittance [%] of each polarizer at a position separated from the end portion of the image display unit by 10 mm.

10. The image display device according to claim 2,
wherein the image display device is bendable between the adjacent image display units.

11. The image display device according to claim 2,
wherein the image display units are arranged one-dimensionally or two-dimensionally.

12. The image display device according to claim 11,
wherein the image display units are separable.

13. The image display device according to claim 2,
wherein the image display units are organic electroluminescence display elements.

14. The image display device according to claim 2,
wherein the image display units are LED display elements or micro-LED display elements.

15. The image display device according to claim 3,
wherein the image display device is bendable between the adjacent image display units.

16. The image display device according to claim 3,
wherein the image display units are arranged one-dimensionally or two-dimensionally.

17. The image display device according to claim 16,
wherein the image display units are separable.

18. The image display device according to claim 3,
wherein the image display units are organic electroluminescence display elements.

19. The image display device according to claim 3,
wherein the image display units are LED display elements or micro-LED display elements.

20. The image display device according to claim 4,
wherein the image display units are arranged one-dimensionally or two-dimensionally.
